(19) United States
(12) Patent Application Publication
(10) Pub. No.: US 2019/0181251 A1
(43) Pub. Date: Jun. 13, 2019

(54) MESH STRUCTURE FOR HETEROJUNCTION BIPOLAR TRANSISTORS FOR RF APPLICATIONS

(71) Applicant: QUALCOMM Incorporated, San Diego, CA (US)

(72) Inventor: Ranadeep DUTTA, Del Mar, CA (US)

(21) Appl. No.: 15/834,100

(22) Filed: Dec. 7, 2017

(51) Int. Cl. H01L 29/737; H01L 29/08; H01L 29/10

(52) U.S. Cl. CPC H01L 29/7371; H01L 29/0821; H01L 2924/2027; H01L 29/0817; H03F 2200/453; H01L 29/1004

(57) ABSTRACT

In certain aspects, a heterojunction bipolar transistor (HBT) comprises a collector mesa, a base mesa on the collector mesa, and an emitter mesa on the base mesa. The emitter mesa has a plurality of openings. The HBT further comprises a plurality of base metals in the plurality of openings connected to the base mesa.

### BACKGROUND

### Field

Aspects of the present disclosure relate generally to a heterojunction bipolar transistor, and more particularly, to manufacturing methods and arrangement of the emitter mesa, base mesa, and collector mesa of the heterojunction bipolar transistor for RF applications.

### Background

The heterojunction bipolar transistor (HBT) is a type of bipolar junction transistor (BJT) that uses different semiconductor materials for the emitter and base regions, creating a heterojunction. The HBT improves on the BJT in that the HBT can handle signals of very high frequencies, up to several hundred GHz. The HBT is commonly used in modern ultrafast circuits, mostly radio-frequency (RF) systems, and in applications requiring a high power efficiency, such as RF power amplifiers in cellular phones.

Conventional heterojunction bipolar transistor layout arranges the emitter in stripes. However, an HBT using such a structure faces a few challenges. For any given emitter mesa area (set by the required output RF power), the base mesa occupies a very large area. A typical ratio of the base mesa to emitter mesa area on a conventional HBT unit cell is around 2.4. An HBT's base-collector junction capacitance (Cbc) is a very key limiter of device performance, such as power gain, particularly at a high frequency. The large Cbc from the large base mesa area compromises the device's power gain and efficiency. An HBT with a stripe layout also occupies a large footprint to accommodate the emitter mesa area required to deliver a given output power, leading to large die size and high manufacturing cost.

Accordingly, it would be beneficial to provide an improved HBT structure and an improved manufacturing method that reduce area and improve the device performance.

### SUMMARY

The following presents a simplified summary of one or more implementations to provide a basic understanding of such implementations. This summary is not an extensive overview of all contemplated implementations, and is intended to neither identify key nor critical elements of all implementations nor delineate the scope of any or all implementations. The sole purpose of the summary is to present concepts relate to one or more implementations in a simplified form as a prelude to a more detailed description that is presented later.

In one aspect, a heterojunction bipolar transistor (HBT) comprises a collector mesa, a base mesa on the collector mesa, and an emitter mesa on the base mesa. The emitter mesa has a plurality of openings. The HBT further comprises a plurality of base metals in the plurality of openings connected to the base mesa.

In another aspect, a method comprises providing a wafer with a collector mesa stack, a base mesa stack, and an emitter mesa stack; patterning the emitter mesa stack to define an emitter mesa having a plurality of openings; providing a plurality of base metals in the plurality of openings connected to the base mesa stack; and patterning the base mesa stack to define a base mesa.

To accomplish the foregoing and related ends, one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 illustrates a top-down view of an example HBT with a stripe layout.

FIG. 2 illustrates an exemplary cross-section of FIG. 1 along line A-A′.

FIG. 3 illustrate another exemplary cross-section of FIG. 1 along line A-A′.

FIG. 4 illustrates an exemplary implementation of an HBT with the emitter mesa arranged in a mesh structure according to certain aspects of the present disclosure.

FIG. 5 illustrates still another exemplary implementation of an HBT with the emitter mesa arranged in a mesh structure according to certain aspects of the present disclosure.

FIG. 6 illustrates an exemplary cross-section of FIG. 5 along line B-B′ according to certain aspects of the present disclosure.

FIG. 7 illustrates still another exemplary implementation of an HBT with the emitter mesa arranged in a mesh structure according to certain aspects of the present disclosure.

FIGS. 8a-8g illustrate an exemplary process flow of making an HBT according to certain aspects of the present disclosure.

FIG. 9 illustrates an exemplary method for manufacturing an HBT with the emitter mesa arranged in a mesh structure according to certain aspects of the present disclosure.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing an understanding of the various concepts. However, it will be apparent to those skilled in the art that these concepts may be practiced without these specific details. In some instances, well-known structures and components are shown in block diagram form in order to avoid obscuring such concepts.

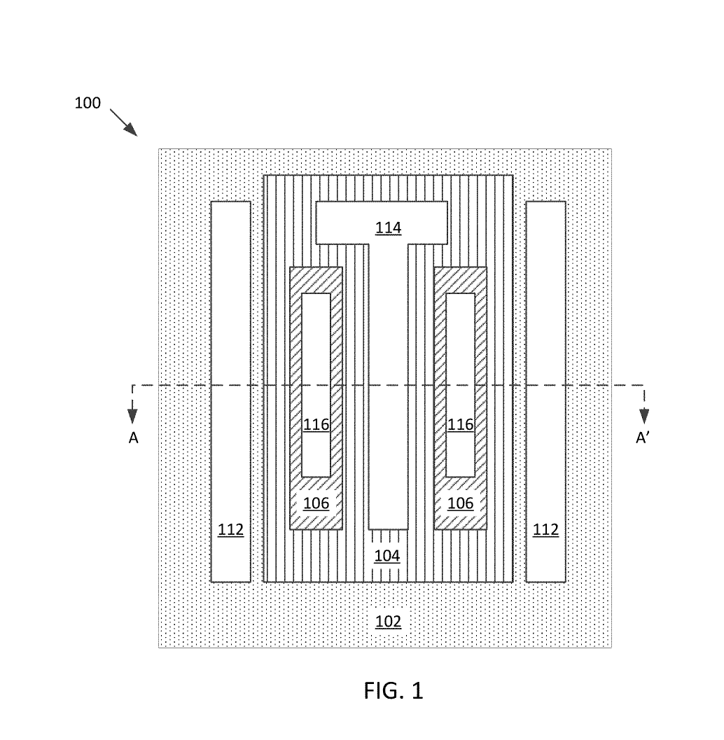

An HBT's base-collector capacitance (Cbc) is a very key limiter of its power gain, particularly at high frequencies. A conventional HBT often arranges the emitter mesa in stripes, which results in high Cbc. FIG. 1 illustrates a top-down view of an example HBT with the stripe layout. The HBT 100 comprises a collector mesa 102 and a base mesa 104 on the collector mesa 102. The HBT 100 further comprises a stripe of base metal 114 on the base mesa 104 to provide the connection to the base. An emitter mesa composed of a plurality of stripes 106 is on the base mesa 104. To accommodate more base metals or larger emitter mesa, more base metals 114 may be placed interleaved with the emitter mesa stripes 106. In addition, the HBT 100 also comprises a plurality of emitter metals 116 on the plurality of emitter mesa stripes 106 to provide electrical connection to the emitter. One or more collector metals 112 are placed on the collector mesa 102 to provide electrical connection to the collector.

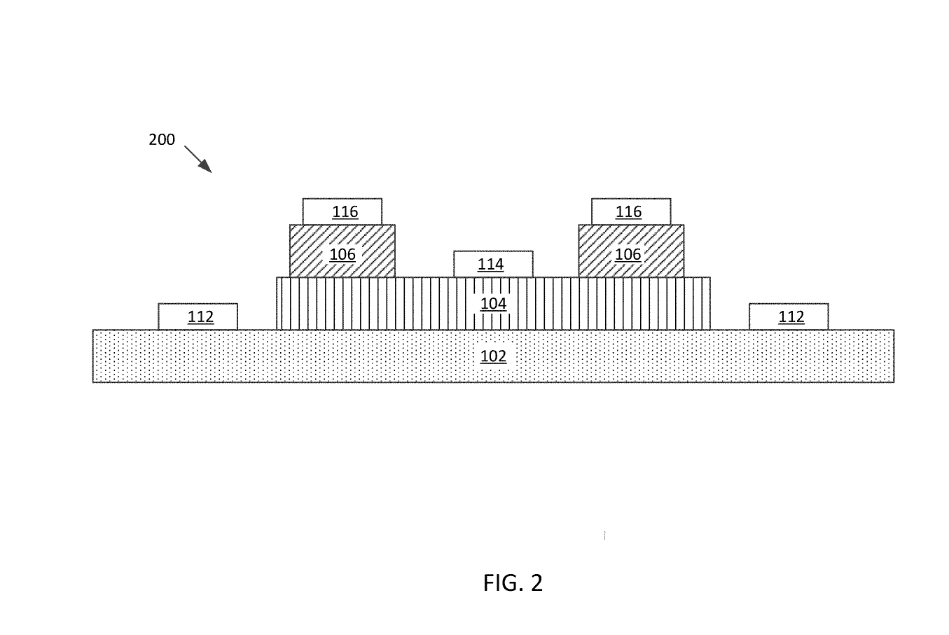

FIG. 2 illustrates an exemplary cross-section of FIG. 1 along line A-A′. The cross-section 200 comprises the collector mesa 102, the base mesa 104 on the collector mesa 102, and the emitter mesas 106 on the base mesa 104. One or more stripes of the base metal 114, one or more stripes of emitter metals 116, and one or more stripes of collector metal 112 are placed (e.g., by deposition process) on the base mesa 104, the emitter mesas 106, and the collector mesa 102, respectively.

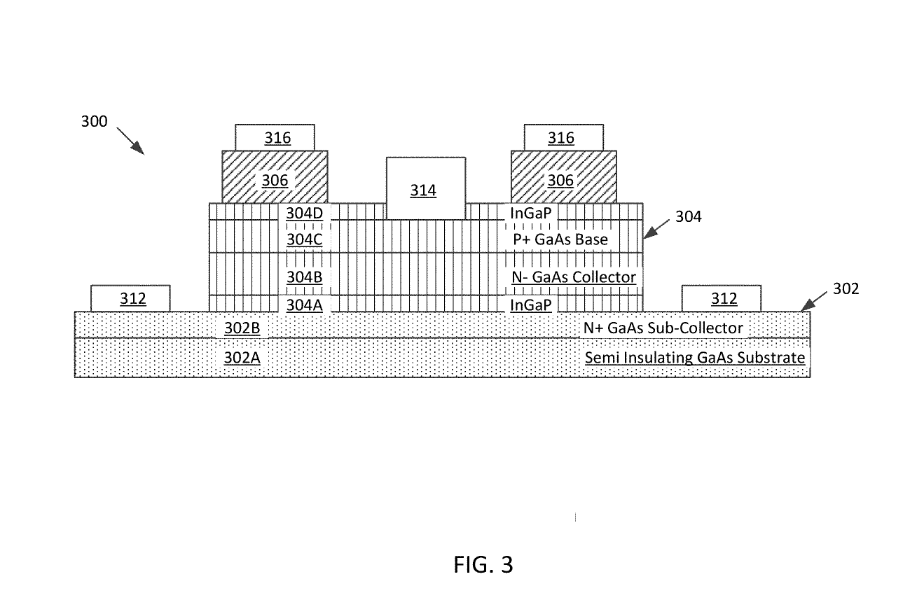

Although each of the collector mesa, the base mesa, and the emitter mesa is illustrated as a single layer in the cross-section 200, one should understand that each layer could include multiple sub-layers. FIG. 3 illustrates an exemplary cross-section of an NPN HBT. The NPN HBT 300 comprises a collector mesa 302, a base mesa 304, and an emitter mesa 306. The collector mesa comprises two sub-layers in this example: a semi insulating GaAs substrate 302A and an N+ GaAs sub-collector 302B. Similarly, the base mesa 304 also comprises multiple sub-layers in this example: a first InGaP etch stop layer 304A, an N− GaAs collector 304B, a P+ GaAs base 304C, and a second InGaP etch stop layer 304D. The N+ GaAs sub-collector 302B, the first InGaP etch stop layer 304A, and the N− GaAs collector 304B forms the collector of the HBT 300. The NPN HBT 300 further comprises one or more stripes of the base metal 314, one or more stripes of emitter metals 316, and one or more stripes of collector metal 312 placed (e.g., by deposition process) on the base mesa 304, the emitter mesas 306, and the collector mesa 302, respectively.

The layout and structure illustrated in FIG. 1 suffer from large base-collector junction area for any given emitter mesa area (set by the required current output RF power). The resulting large Cbc compromises the HBT's power gain and efficiency. According to certain aspects of the present disclosure, to reduce the base-collector junction area and Cbc, an emitter mesa may be arranged in a mesh structure, along with associated emitter metal. The openings of the mesh can be shaped in rectangular or hexagon or other suitable fashions. Metal pickups for the HBT base are arranged inside the openings of the mesh. The structure may further include an optional base metal donut surrounding the emitter mesh to further lower the base resistance. Optional base metal provides additional optimization space, trading off base resistance (Rb) with Cbc. The optional base metal donut is interconnected with the base metal dots inside the emitter mesh openings. The structure reduces the base mesa area/emitter mesa area ratio to be under 1.8. In addition, the structure achieves over 25% performance improvement over structures illustrated in FIG. 1.

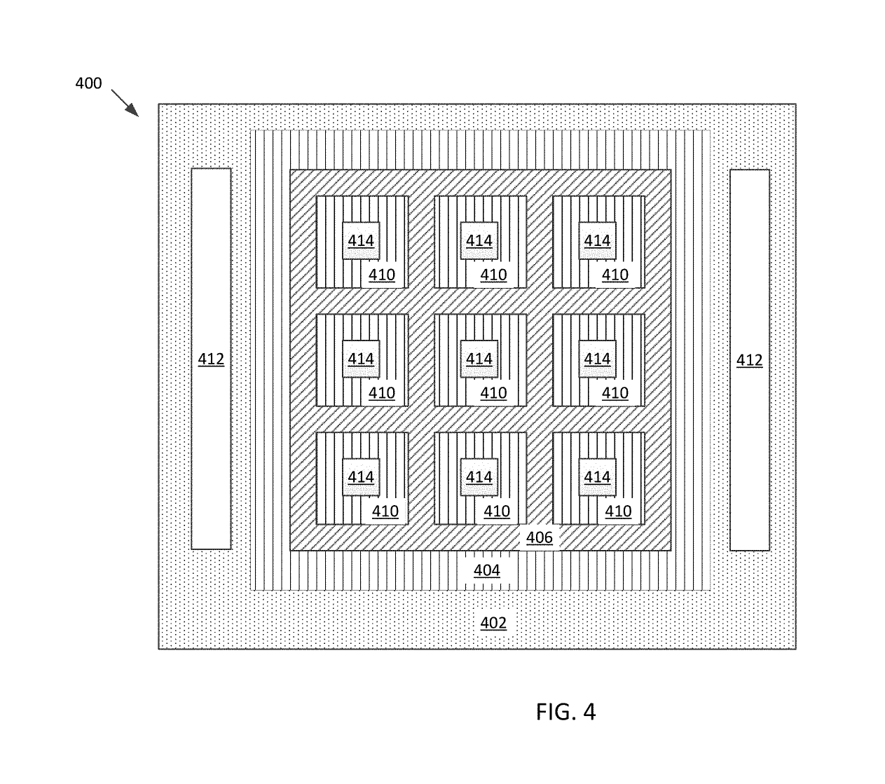

FIG. 4 illustrates an exemplary implementation of an HBT with the emitter mesa arranged in a mesh structure according to certain aspects of the present disclosure. An HBT 400 comprises a collector mesa 402, a base mesa 404 on the collector mesa 402, and an emitter mesa 406 on the base mesa 404. The emitter mesa 406 is arranged in a mesh like structure. The emitter mesa 406 has a plurality of openings 410. The plurality of openings 410 provides windows for a plurality of base metals 414 to be placed and connected to the base mesa 404. The plurality of base metals 414 are connected through another layer (or layers) of metal (not shown) and are electrically coupled to each other.

The plurality of openings 410 may be in any shape, such as square (as illustrated in FIG. 4), rectangular, hexagon, etc. The size and/or the shape for each of the plurality of openings 410 may be different. The plurality of openings 410 may have same size and/or same shape for ease of the design and/or for high packing density. Each of the plurality of openings 410 is big enough to accommodate base metals 414 inside the opening, including the size of each of the plurality of base metals 414 itself and the necessary spacing between each of the plurality of base metals 414 and the emitter mesa 406. Thus, the minimum size of the plurality of openings 410 is limited by the process technology used. Similarly, the spacing between one of the plurality of openings 410 to the neighboring one of the plurality of openings 410 is also a design choice with the minimum spacing limited by the process technology used. However, the spacing may be any size that is larger than or equal to the minimum allowed by the process technology.

Different sizes of HBTs are needed for different applications. For example, if an HBT is used as a power amplifier, the size of the HBT is chosen to meet a particular output power requirement. The mesh like emitter mesa structure provides flexibility in choosing the size of an HBT and the arrangement of the collector, base, and emitter. The number of openings 310 may be varied and can be any integer. For example, there may be four openings arranged in a 2×2 array. There can be more or less than 4 openings, including 1 opening. The arrangement of the plurality of openings 310 is flexible and is not limited to the square array. Other array is possible, such as 2×2, 3×3, or 3×1 array, just to give a few examples. By arranging HBT's emitter mesa in mesh structure (e.g., having plurality of openings), the packing density is improved. The base mesa area/emitter mesa area ratio may be reduced to be lower than 1.8.

The HBT 400 further comprises one or more emitter metal (not shown) on the emitter mesa 406. The emitter metal may fully or partially cover the emitter mesa 406. The HBT 400 also comprises one or more collector metals 412 on the collector mesa 402 to provide connection to the collector of the HBT 400.

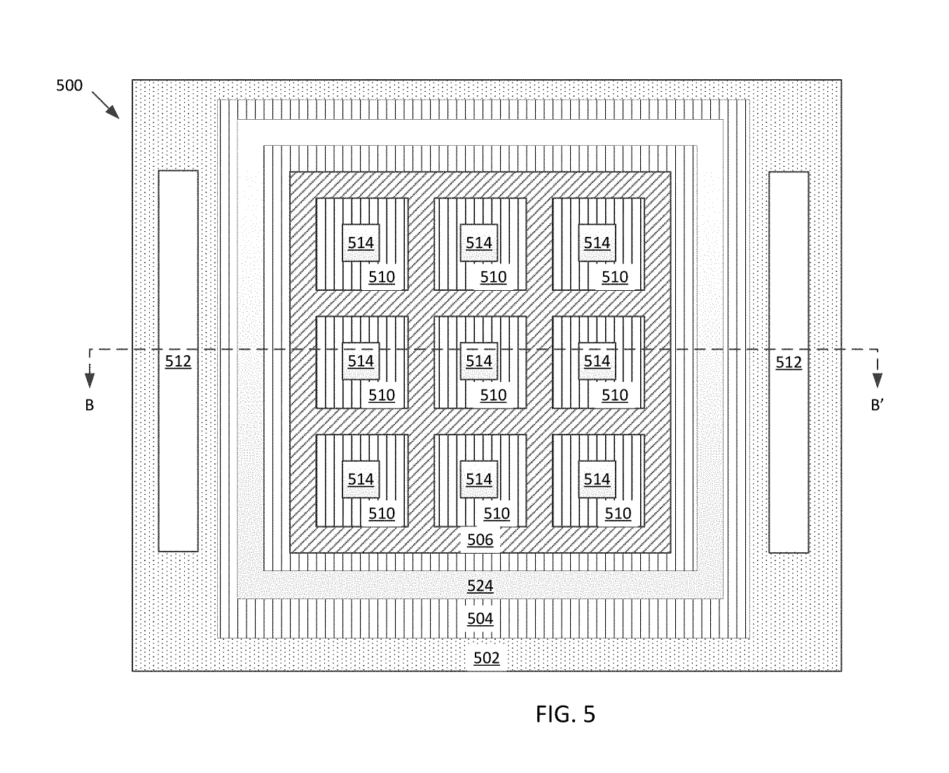

To lower the base resistance further, an optional base metal may be provided surrounding the emitter mesa. FIG. 5 illustrates an exemplary implementation of an HBT with its emitter mesa arranged in a mesh structure and with an optional base metal surrounding the emitter mesa. Like the HBT 400, an HBT 500 comprises a collector mesa 502, a base mesa 504 on the collector mesa 502, and an emitter mesa 506 on the base mesa 504. The emitter mesa 506 is arranged in a mesh like structure. The emitter mesa 506 has a plurality of openings 510. The plurality of openings 510 provides windows for a plurality of base metals 514 to be placed and connected to the base mesa 504. The plurality of base metals 514 are connected through another layer (or layers) of metal (not shown) and are electrically coupled to each other. The emitter metal (not shown) is on the emitter mesa 506. The emitter metal may fully or partially cover the emitter mesa 506. The HBT 500 also comprises one or more collector metals 512 on the collector mesa 502 to provide connection to the collector of the HBT 500.

In addition, the HBT 500 further comprises an optional base metal 524 surrounding the emitter mesa 506. The optional base metal 524 may be in donut shape (as illustrated in FIG. 5) or may be one or more stripes of metals (not illustrated). The optional base metal 524 is an outer base metal that is outside of the emitter mesa mesh. The optional base metal 524 is connected to the plurality of base metals 514 through another layer (or layers) of metal (not shown) so that the optional base metal 524 and the plurality of base metals 514 are electrically coupled. The optional base metal 524 yields a lower base resistance (Rb) but may increase Cbc. This provides an additional optimization space, trading off Rb with Cbc.

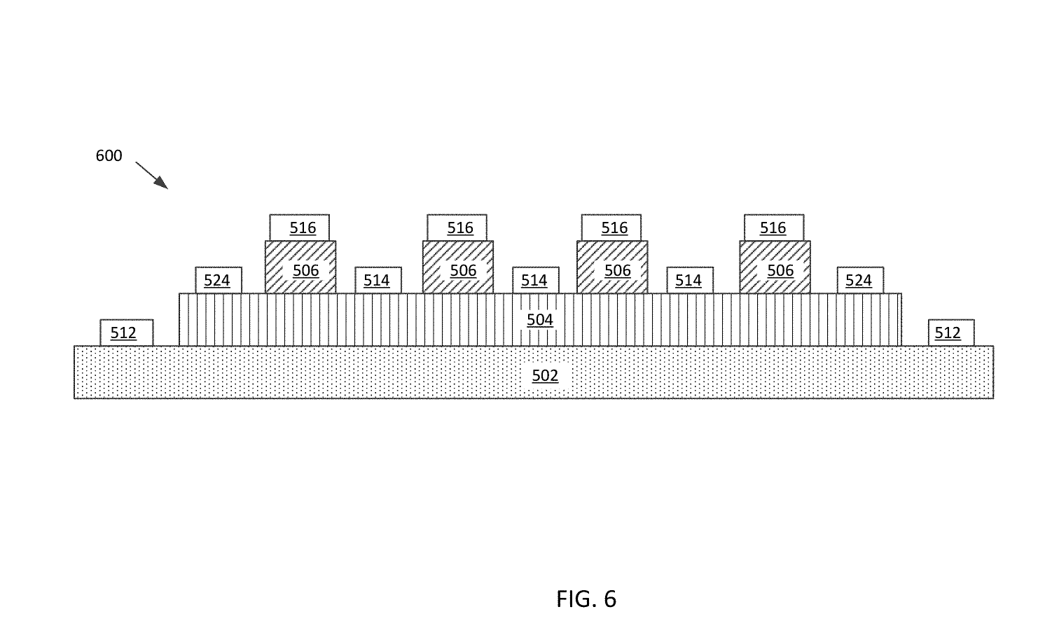

FIG. 6 illustrates an exemplary cross-section of FIG. 5 along line B-B′ according to certain aspects of the present disclosure. The cross-section 600 comprises the collector mesa 502, the base mesa 504 on the collector mesa 502, and the emitter mesa 506 on the base mesa 504. The cross-section 600 also includes the optional base metal 524.

Although each of the collector mesa, the base mesa, and the emitter mesa is illustrated as a single layer in the cross-section 600, one should understand that each layer could include multiple sub-layers, similar to the cross-section 300 in FIG. 3. For example, in an NPN HBT, the collector mesa 502 may comprise an intrinsic or lightly doped GaAs substrate and an N+ GaAs sub-collector. The collector metal may connect to the N+ GaAs sub-collector and electrically couple to the collector of the HBT. The emitter mesa may comprise an intrinsic InGaAs sub-layer, followed by a lightly N doped (e.g., 5E17) InGaP layer and a high N+ doped (e.g., 1E19) InGaAs layer.

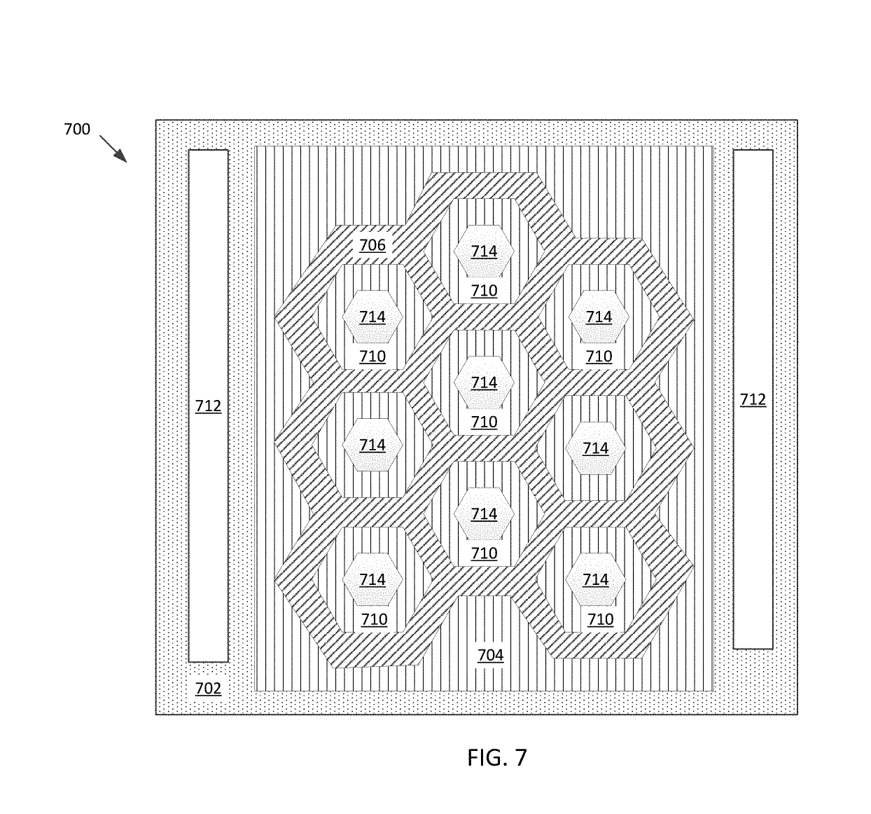

FIG. 7 illustrates another exemplary implementation of an HBT with its emitter mesa arranged in a mesh structure according to certain aspects of the present disclosure. The HBT 700 is similar to the HBT 300 but with a different emitter mesa mesh structure. The HBT 700 comprises a collector mesa 702, a base mesa 704 on the collector mesa 702, and an emitter mesa 706 on the base mesa 704. The emitter mesa 706 is arranged in a mesh like structure. The emitter mesa 706 has a plurality of openings 710. The plurality of openings 710 provides windows for a plurality of base metals 714 to be placed and connected to the base mesa 704. The plurality of base metals 714 are connected through another layer (or layers) of metal (not shown) and electrically coupled to each other. The emitter metal (not shown) is on the emitter mesa 706. The emitter metal may fully or partially cover the emitter mesa 706. The HBT 700 also comprises one or more collector metals 712 on the collector mesa 702 to provide connection to the collector of the HBT 700.

Unlike the emitter mesa 400 whose plurality of openings 410 are in square shape, the plurality of openings 710 are in hexagon shape. The hexagon shape provides higher packing density than the square shape, resulting in smaller area for an HBT under same output power. In addition to the hexagon shape openings, the plurality of base metals 714 may be in hexagon shape to maximize the connection to the base and to reduce the base resistance.

Similar to the HBT in FIGS. 5 and 6, the HBT 700 may comprise an optional base metal (not shown) surrounding the emitter mesa 706. The optional base metal may be in donut shape (as illustrated in FIG. 5) or may include one or more stripes of metals. The optional base metal is connected to the plurality of base metals 714 through another layer (or layers) of metal (not shown) so that the optional base metal and the plurality of base metals 714 are electrically coupled.

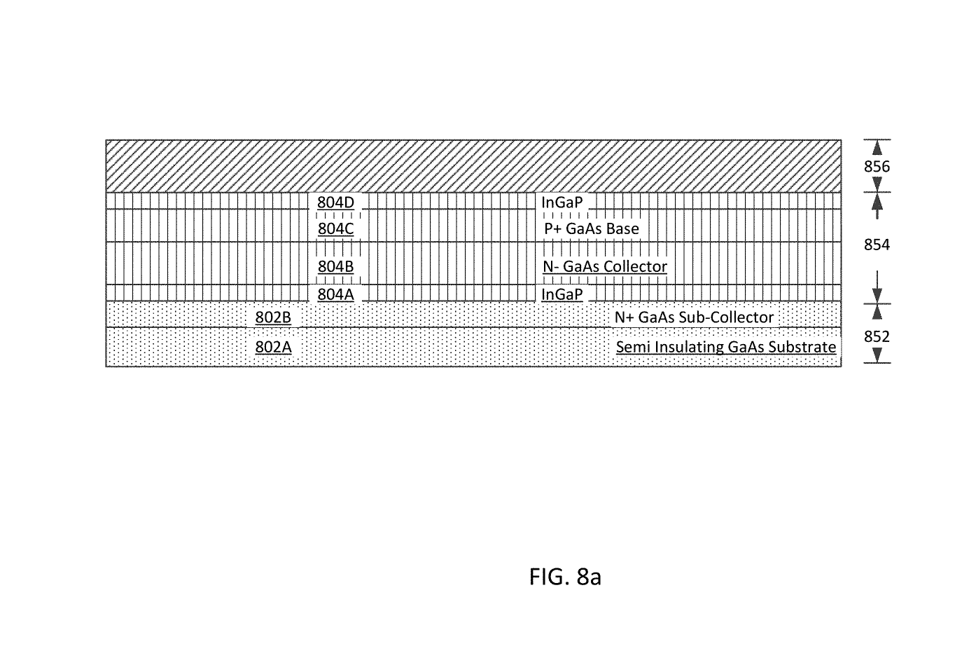

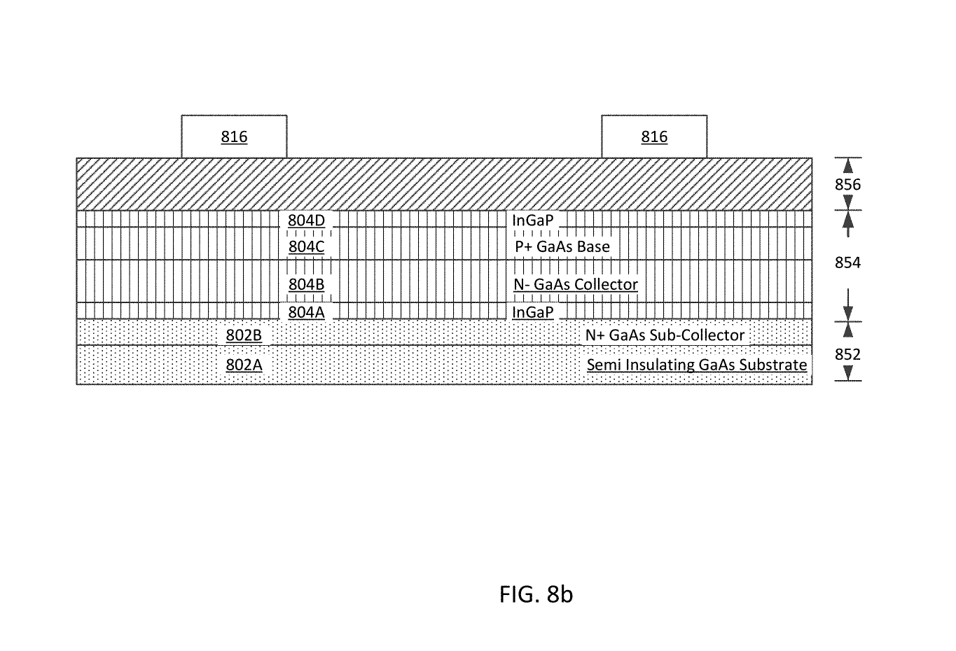

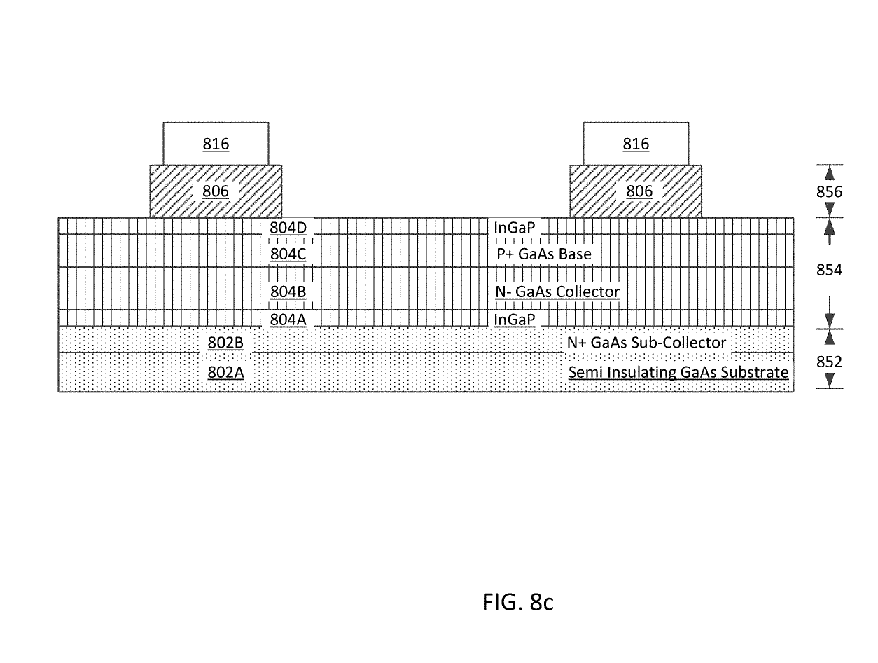

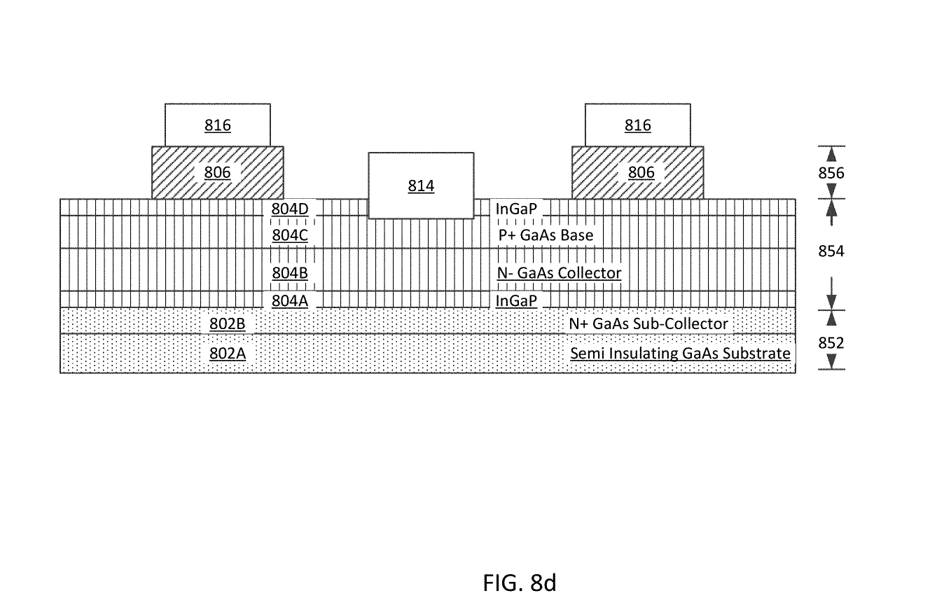

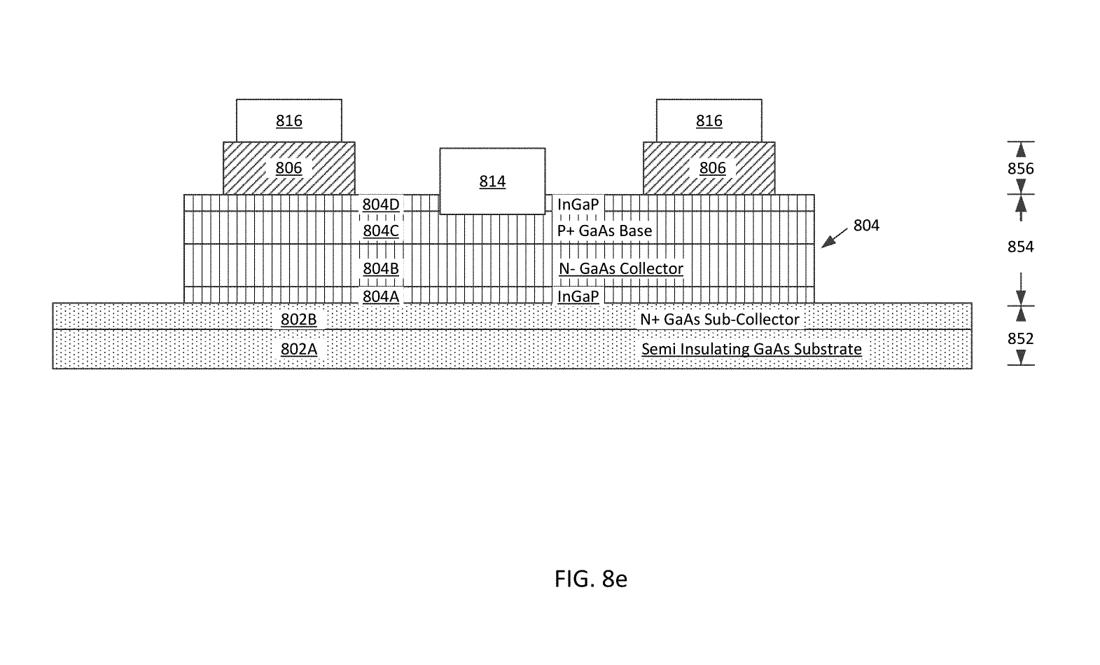

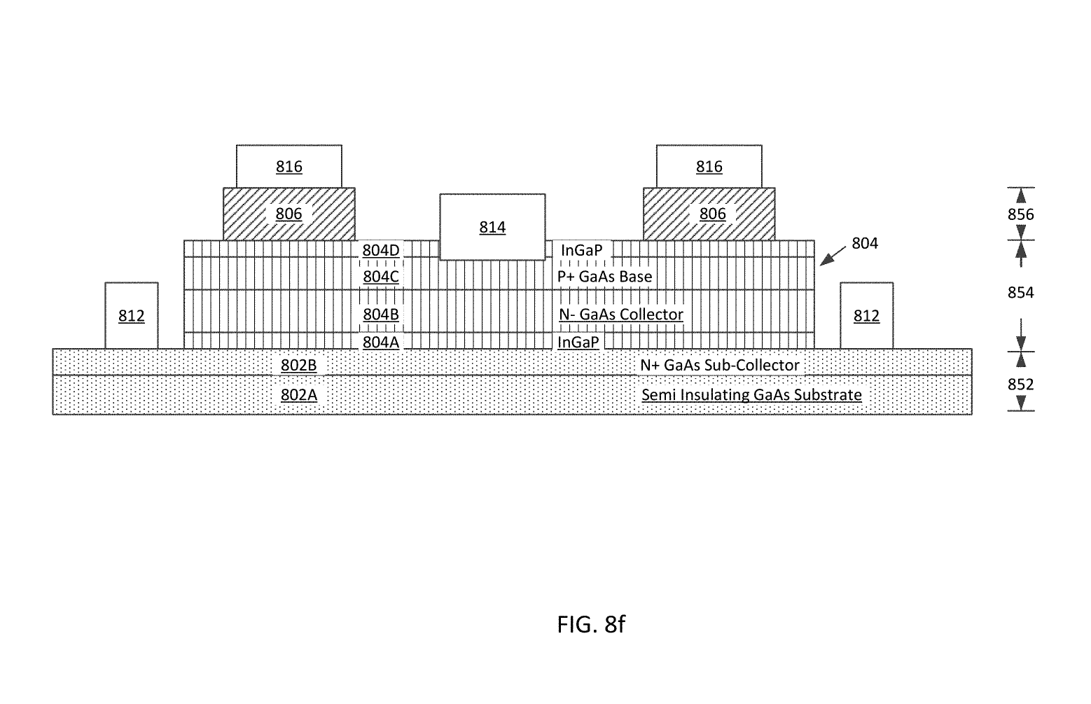

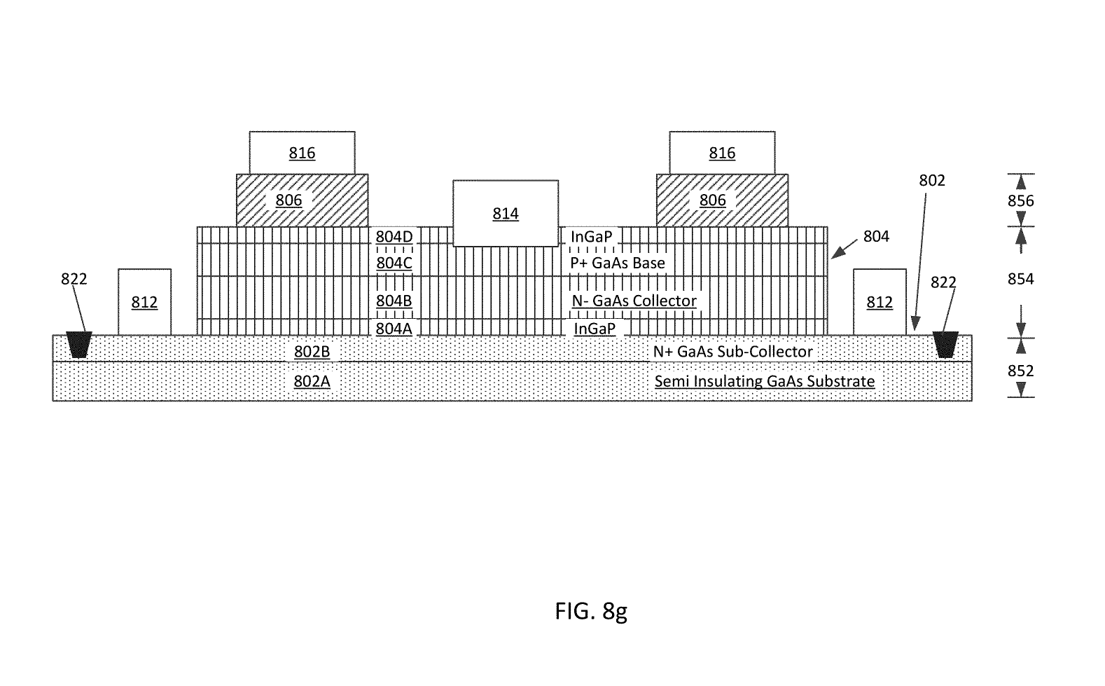

FIGS. 8a-8g illustrate an exemplary process flow of making an HBT. FIG. 8a shows a starting wafer with required epi stacks. The wafer comprises a collector mesa stack 852, a base mesa stack 854, and an emitter mesa stack 856. The collector mesa stack 852, the base mesa stack 854, and the emitter mesa stack 856 are so defined as they are the starting stacks for the collector mesa, base mesa, and emitter mesa of an HBT, respectively. Each of the collector mesa stack 852, the base mesa stack 854, and the emitter mesa stack 856 may comprises multiple sub-layers. For example, the collector mesa stack 852 includes a layer of semi-insulating substrate 802A (e.g., comprising intrinsic GaAs) and a layer of sub-collector 802B (e.g., comprising N+ GaAs). The base mesa stack 854 includes a first etch stop layer 804A (e.g., comprising InGaP), a collector layer 804B (e.g. comprising N− GaAs), a base layer 804C (e.g., comprising P+ GaAs), and a second etch stop layer 804D (e.g., comprising InGaP). FIG. 8b illustrates part of the wafer after the placement of the emitter metal of the HBT. One or more emitter metal 816 on the emitter mesa stack 856 are patterned and defined (such as lithographic patterning and etching). FIG. 8c illustrates part of the wafer after the patterning of emitter mesa by etching the emitter mesa stack 856. The emitter metal stack 856 is patterned and etched to form a desired pattern as an emitter mesa 806. The emitter mesa 806 may be formed in a variety of shapes, including the shapes illustrated in FIGS. 4, 5, and 7. In FIG. 8d, the base metal 814 is patterned and defined on the base mesa stack 854. The second etch stop layer 804D is patterned and etched so that the base metal 814 contacts the collector layer 804C. FIG. 8e illustrates the structure after formation of base mesa. The base mesa stack 854 is patterned and etched to form the base mesa 804, including patterning and etching layers 804A-804D. In FIG. 8f, one or more collector metals 812 are patterned and defined on the collector mesa stack 852. Finally, as illustrated in FIG. 8g, an implant isolation ring 822 may surround the HBT. The implant isolation ring defines the collector mesa 802 and forms the boundary of the HBT.

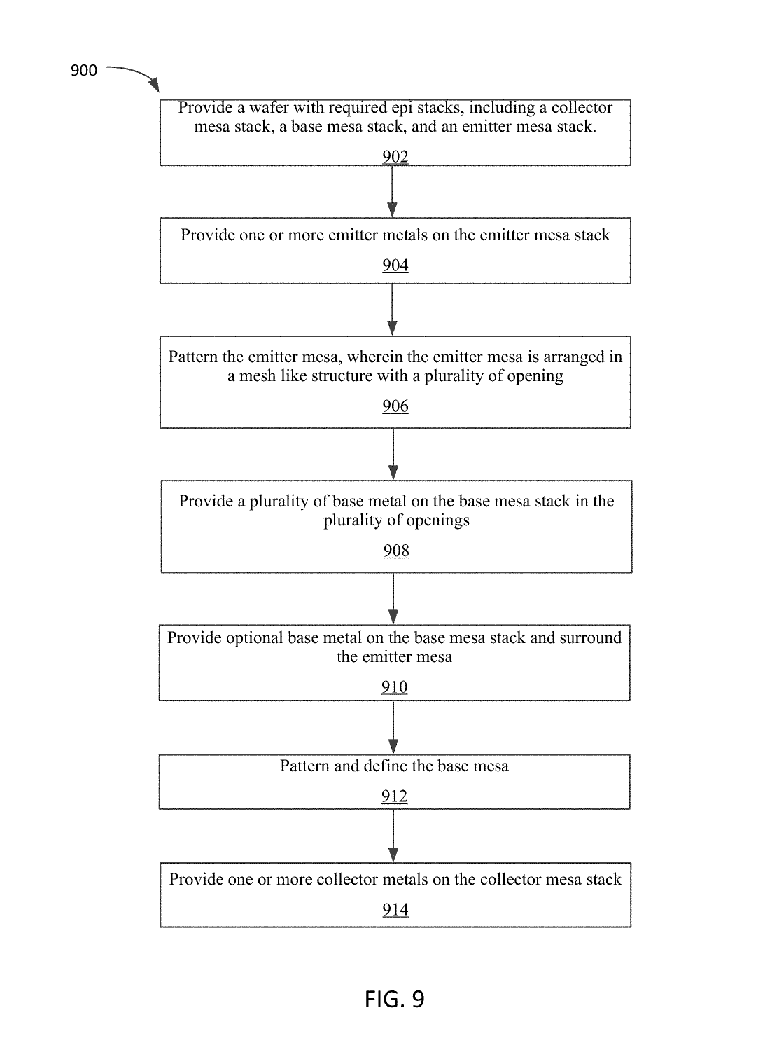

FIG. 9 illustrates an exemplary method for manufacturing an HBT with its emitter mesa arranged in a mesh structure according to certain aspects of the present disclosure. The description of method 900 below and the process flow diagrams provided in FIG. 9 are merely as illustrative examples and are not intended to require or imply that the operations of the various aspects must be performed in the order presented

The HBT manufacturing method 900 starts with a wafer with required epi stacks. At 902, a wafer with required epi stacks, including a collector mesa stack (e.g., the collector mesa stack 852), a base mesa stack (e.g., the base mesa stack 854), and an emitter mesa stack (e.g., the emitter mesa stack 856) is provided. Each mesa stack may comprise multiple sub-layers. For example, for an NPN HBT, the collector mesa stack may include a layer of intrinsic GaAs semi-insulating substrate (e.g., the semi-insulating substrate 802A) and a layer of N+ GaAs sub-collector (e.g., the sub-collector 802B). The base mesa stack may include a first InGaP etch stop layer (e.g., the etch stop layer 804A)), an N− GaAs collector layer (e.g., the collector layer 804B), a P+ GaAs base layer (e.g., the base layer 804C), and a second InGaP etch stop layer (e.g., the etch stop layer 804D).

At 904, one or more emitter metals (e.g., the emitter metals 516 or 816) are placed on the emitter mesa stack.

At 906, the emitter mesa is patterned and formed through a suitable process such as etching. The emitter mesa comprises a plurality of openings (e.g., the plurality of openings 410, 510, or 710). The plurality of openings may be in any shape, such as square (as illustrated in FIG. 4), rectangular, hexagon (as illustrated in FIG. 7), etc. The size and/or the shape for each of the plurality of openings may be different or may be same. Each of the plurality of openings is big enough to accommodate a base metal (e.g., the base metal 414, 514, or 714), including the size of the base metal itself and the necessary spacing between the base metal and the emitter mesa. Thus, the minimum size of the plurality of openings is limited by the process technology used. Similarly, the spacing between one opening to the neighboring opening is also a design choice and the minimum is limited by the process technology used.

At 908, a plurality of base metals (e.g., the plurality of base metals 414, 514, or 714) is provided in the plurality of openings. The plurality of base metals is on the base mesa stack and provides connection to the base of the HBT. The plurality of base metals may be with the same shape as the plurality of openings. The plurality of base metals is connected through another layer (or layers) of metal and is electrically coupled to each other.

At 910, an optional base metal (outer base metal) (e.g., the base metal 524) may be placed on the base mesa stack and connected to the base metals in the plurality of openings. The optional base metal surrounds the emitter mesa and may yield a low base resistance. The optional base metal is electrically coupled to the plurality of base metals through another layer (or layers) of metal.

At 912, the base mesa (e.g., the base mesa 404, 504, 704, or 804) is patterned and formed through process such as etching.

At 914, one or more collector metals (e.g., the collector metals 412, 512, 712, or 812 are placed on the collector mesa stack.

Furthermore, a collector mesa may be further defined by placing isolation ring in the collector mesa stack. The isolation ring also forms the boundary of the HBT.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A heterojunction bipolar transistor (HBT), comprising:
a collector mesa;
a base mesa on the collector mesa;
an emitter mesa on the base mesa, wherein the emitter mesa is arranged in a mesh structure with a plurality of openings exposing a top surface of the base mesa at bottoms of the plurality of openings, and wherein the collector mesa, the base mesa, and the emitter mesa form the HBT; and
a plurality of base metals in the plurality of openings connected to the base mesa.

2. The heterojunction bipolar transistor (HBT) of claim 1 further comprising an outer base metal arranged outside the emitter mesa and connected to the base mesa, wherein the plurality of base metals and the outer base metal are electrically coupled.

3. The heterojunction bipolar transistor (HBT) of claim 2, wherein the outer base metal is arranged to surround the emitter mesa.

4. The heterojunction bipolar transistor (HBT) of claim 1 further comprising an emitter metal coupled to the emitter mesa.

5. The heterojunction bipolar transistor (HBT) of claim 1 further comprising a collector metal coupled to the collector mesa.

6. The heterojunction bipolar transistor (HBT) of claim 1, wherein each of the plurality of openings has a same size.

7. The heterojunction bipolar transistor (HBT) of claim 6, wherein each of the plurality of openings is in square shape.

8. The heterojunction bipolar transistor (HBT) of claim 6, wherein a number of the plurality of openings is at least four.

9. The heterojunction bipolar transistor (HBT) of claim 6, wherein the plurality of openings is arranged in an array.

10. The heterojunction bipolar transistor (HBT) of claim 9, wherein the plurality of openings is arranged in a 2×2, 3×3, or 3×1 array.

11. The heterojunction bipolar transistor (HBT) of claim 6, wherein each of the plurality of opening is in hexagon shape.

12. The heterojunction bipolar transistor (HBT) of claim 11, wherein each of the plurality of base metals is in hexagon shape.

13. The heterojunction bipolar transistor (HBT) of claim 1, wherein a spacing between the emitter mesa and the plurality of base metals is a minimum size allowed by a process technology used.

14. The heterojunction bipolar transistor (HBT) of claim 1, wherein a ratio of an area of the base mesa to the area of the emitter mesa is less than 1.8.

15-26. (canceled)
